(19) United States
(12) Patent Application Publication
(10) Pub. No.: US 2008/0101451 A1
(43) Pub. Date: May 1, 2008

(54) Method and Apparatus for Subblock-Wise Frequency Domain Equalization

(76) Inventors: Haifeng Wang, Shanghai (CN); Jorma Lilleberg, Oulu (FI); Wei Li, JiangSu Provice (CN); Ming Chen, Nanjing (CN); Shixin Cheng, Nanjing (CN)

Correspondence Address: DITTHAVONG MORI & STEINER, P.C., 918 Prince Street, Alexandria, VA, 22314, US

(21) Appl. No.: 11/733,503

(22) Filed: Apr. 10, 2007

(30) Foreign Application Priority Data
Oct. 30, 2006 (EP) EP 06 022 630.5

(51) Int. Cl. H03K 5/159

(52) U.S. Cl. 375/232

(57) ABSTRACT

An approach is provided for subblock-wise frequency domain equalization, wherein a data block of a received signal is segmented into at least two subblocks at a receiving end of a transmission channel. The subblocks are then equalized separately in the frequency domain, and equalized subblocks are combined to obtain an equalized signal. Thereby, Doppler induced interference can be suppressed to achieve enhanced robustness to high Doppler and compensate performance degradation due to rapidly varying channels.

### FIELD OF THE INVENTION

The invention, according to various embodiments, relates to communications, and particularly, to signal processing.

### BACKGROUND OF THE INVENTION

Orthogonal frequency division multiplexing (OFDM) has been adopted in digital audio broadcasting (DAB), digital video broadcasting (DVB), high speed modems over digital subscriber lines (xDSL), and broadband wireless access field recently, such as wireless local area networks (WLAN) in IEEE (Institute of Electrical and Electronics Engineers) standard 802.11a and 802.11g. In OFDM, multiple modulated subcarriers are transmitted in parallel. Each occupies only a very narrow bandwidth. Since only the amplitude and phase of each subcarrier is affected by the channel, compensation of frequency selective fading can be performed by compensating for each subchannel's amplitude and phase. OFDM signal processing can be a carried out relatively simply by using fast Fourier transforms (FFTs), at the transmitter and receiver, respectively.

Channel estimation and tracking pose real problems in wireless communication systems. An alternative to estimating the channel is to adaptively equalize the received symbols. Frequency domain equalization (FDE) can be regarded as the frequency domain analog of what is done by a conventional linear time domain equalizer. For channels with severe delay spread it is simpler than corresponding time domain equalization for the same reason that OFDM is simpler because of the FFT operations and the simple channel inversion operation.

Furthermore, by appending a cyclic prefix (CP) of enough length in front of each data block, inter-block interference (IBI) due to multi-path channel can be removed. Additionally, low complexity one-tap frequency domain equalization (FDE) can be used to compensate signal distortions due to multi-path channels. The signal transformation between time domain and frequency domain can be effectively implemented by fast Fourier transform (FFT), for example.

However, in high Doppler environment with fast moving terminals, the transmission channel varies even within a single data block. This induces inter-symbol interference (ISI) in the time domain or inter-carrier interference (ICI) in the frequency domain, which cannot be suppressed by the conventional one-tap FDE.

Three major types of algorithms have been proposed to compensate system performance degradation due to high Doppler. Type-I directly applies interference cancellation techniques of multi-user detection (MUD), which have been originally proposed for Code Division Multiple Access (CDMA) systems. Here, processing delay is induced due to multistage operations and error propagation is sensitive to the accuracy of initial estimates. Type-II, also called “self interference cancellation”, compensates the ICI or ISI by increasing signal redundancy. It has very low complexity but its bandwidth efficiency is decreased due to redundancy. Finally, Type-III shortens the transmission block length with smaller-sized FFT operation and is thus more robust to ISI and ICI. However, the system bandwidth efficiency is reduced due to overhead of the cyclic prefix.

### SUMMARY

Therefore, there is a need to provide a method and receiver apparatus for advanced equalization to compensate performance degradation due to rapidly varying channels.

According to an embodiment of the invention, a method comprises:
segmenting at a receiving end of a transmission channel a data block of a received signal into at least two subblocks;
equalizing said subblocks separately in the frequency domain; and
combining equalized subblocks to obtain an equalized signal.

According to another embodiment of the invention, a receiver apparatus comprises:
a segmentation unit for segmenting at a receiving end of a transmission channel a data block of a received signal into at least two subblocks;
at least two equalizer units for equalizing said subblocks separately in the frequency domain; and
a combiner unit for combining equalized subblocks to obtain an equalized signal.

Further, according to another embodiment of the invention, a transceiver apparatus comprises at least one transmitting apparatus as defined above.

In addition, the above object is achieved by a computer program product comprising code means for producing the steps of the above methods when run on a computer device.

Accordingly, full-block-sized symbols are segmented into number of small sub-blocks, equalized separately and combined. This proposed equalization concept provides robustness to high Doppler by suppressing the Doppler induced interference. Performance degradation due to rapidly varying channel can thus be compensated.

Certain embodiments of the invention provide similar performance as conventional schemes with lower block sizes, and outperform conventional schemes with full block size. Also, bandwidth efficiency can still be maintained.

In an aspect of an embodiment, equalization of the subblocks can be based on dedicated channel impulse responses of each subblock.

In an alternative aspect of the embodiment, equalization of the subblocks can be based on channel estimates of preambles and linear interpolation in the frequency domain.

Furthermore, serial-to-parallel conversion and fast Fourier conversion may be performed for each of the subblocks prior to the proposed equalizing.

According to an implementation example, the received signal may be a cyclic prefix assisted single carrier signal or, alternatively, an OFDM signal.

Further advantageous modifications or developments are defined in the dependent claims.

### BRIEF DESCRIPTION OF THE DRAWINGS

The invention, according to certain embodiment, will now be described with reference to the accompanying drawings in which:

FIG. 1 shows a schematic diagram of a transmission system, according to one embodiment of the invention;

FIG. 2 shows a schematic functional diagram indicating a convolution process between a data block an a time-varying channel, according to one embodiment of the invention;

FIG. 3 shows a schematic functional diagram of a subblock-wise equalization process, according to one embodiment of the invention;

FIG. 4 shows schematic block diagram of a transmission system with a subblock-wise equalizer, according to one embodiment of the invention;

FIG. 5 shows a schematic flow diagram of an equalization procedure, according to one embodiment of the invention;

FIGS. 6 to 8 show diagrams indicating bit error rate vs. noise ratio for various alternative systems at different velocities; and

FIG. 9 shows a schematic block diagram of a software-based implementation of one embodiment.

### DESCRIPTION OF EMBODIMENTS

Exemplary embodiments will now be described based on an OFDM transmission system in which a receiver with FDE is employed. However, it will be apparent from the following description and is therefore explicitly stressed that the invention, according to certain embodiments, can be applied to any other transmission architecture in which FDE techniques can be used.

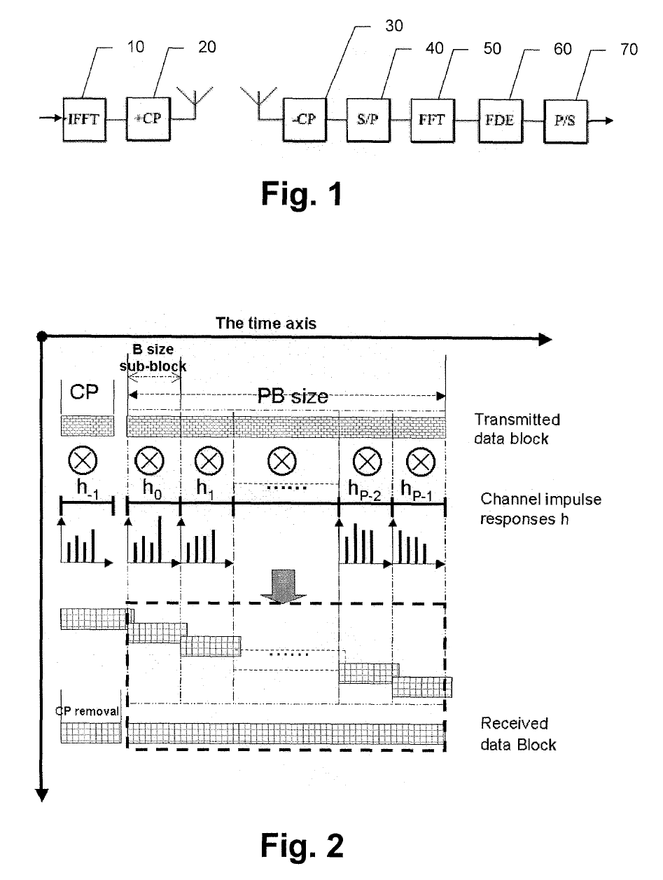

FIG. 1 shows an exemplary OFDM transmission system without channel estimation module, in which a receiver according to one embodiment can be implemented.

In the OFDM system according to FIG. 1, at the transmitter side each data block to be transmitted via a wireless transmission channel is processed in an inverse fast Fourier transformation (IFFT) unit or block 10 which applies an IFFT operation. Then, a cyclic prefix (CP) is added to the transformed data blocks in a prefix addition unit or block 20, and then the transformed data blocks with added CP are transmitted via the wireless transmission channel. The CP typically has a length greater than the maximum delay spread introduced by the transmission channel.

At the receiver side, the CP is removed in a prefix removing unit or block 30 e.g. based on frame synchronization (delay estimation). Then the received signal with removed CP is serial-to-parallel converter in a serial/parallel conversion unit or block 50 and then transformed into the frequency domain by an FFT operation performed in an FFT unit or block 50. Thereafter, the transformed signal is equalized in the frequency domain by an FDE unit or block 60 and then parallel-to-serial converted in a parallel/serial conversion unit or block 70.

The discrete-time received signal with removed CP can be expressed as

y=HQ^{H}x+n (1)

where x=[x₁ x₂ . . . x_{M}]^{T} is the transmitted data with length of M, y=[y₁ y₂ . . . y_{M}]^{T} is the received signals with CP removal, and n=[n₁ n₂ . . . n_{M}]^{T} is the noise vector. Q is the FFT matrix and ( )^{H} denotes the conjugate transposition operation. The channel matrix could be modelled:

$$H = [ \begin{matrix}{h}_{1 , 1} & & & & ⋯ & {h}_{M - 1 , 3} & {h}_{M , 2} \\ {h}_{1 , 2} & {h}_{21} & & & ⋯ & ⋮ & {h}_{M , 3} \\ ⋮ & ⋮ & ⋯ & ⋯ & 0 & & ⋮ \\ {h}_{1 , L} & ⋮ & ⋯ & ⋯ & ⋯ & & \\ & ⋮ & ⋯ & ⋯ & ⋯ & {h}_{M - 1 , 1} & \\ 0 & & & {h}_{M - L + 1 , L} & ⋯ & {h}_{M - 1 , 2} & {h}_{M , 1}\end{matrix} ] \qquad ( 2 )$$

where hᵢⱼ denotes the channel response of j^{th} path at i^{th} symbol duration. Assuming the channel state is approximately quasi-static, the channel matrix H turns to be a cyclic convolution matrix which could be approximated as:

H≈H=Q^{H}ΛQ (3)

where Λ is a diagonal matrix. Then, the signal can be estimated by a linear minimum mean square error (LMMSE) detector in frequency domain such as

[symbol]

=Λ^{H}(ΛΛ^{H}+σ²I)⁻¹Qy (4)

If it is assumed that the channel varies within one OFDM symbol, then the received signal can be modeled as

$$\begin{matrix}y = {HQ}^{H} x + n \\ = \tilde{H} {Q}^{H} x + ( H - \tilde{H} ) {Q}^{H} x + n \\ = \tilde{H} {Q}^{H} x + {E}_{r} {Q}^{H} x + n\end{matrix} \\ {E}_{r} = H - \tilde{H} \qquad ( 5 )$$

where \tilde{H} is the cyclic convolution matrix which can be modeled as in (3), and Eᵣ is the channel variance matrix during one symbol period which induces the residual ISI in time domain or the ICI in frequency domain.

However, as can be noticed here, high Doppler interference could severely impact the system performance because the conventional one-tap frequency domain equalizer cannot suppress the interference induced by high Doppler.

In view of this, a subblock-wise FDE is implemented in the embodiment as a measure against high Doppler interference with varied channel impulse responses within one OFDM symbol. In particular, the convolution progress of one OFDM symbol is approximately decomposed into P subblocks with length of B (M=P×B).

FIG. 2 shows a schematic functional diagram indicating a convolution process between a data block an a time-varying channel. The horizontal axis is to be interpreted as a time axis, while the vertical axis indicates the convolution process or between an OFDM data block and the time-varying channel.

The M-sized OFDM symbol is segmented into P consecutive B-sized sub-blocks. It is assumed that the channel state or channel impulse response is static during each subblock but varies from channel impulse response h₀ to channel impulse response h_{P-1}, subblock by subblock. It can be noticed that the actual received signal (received data block in FIG. 2) can be restored by summing all the decomposed convolutions between the subblocks and time varying channel states.

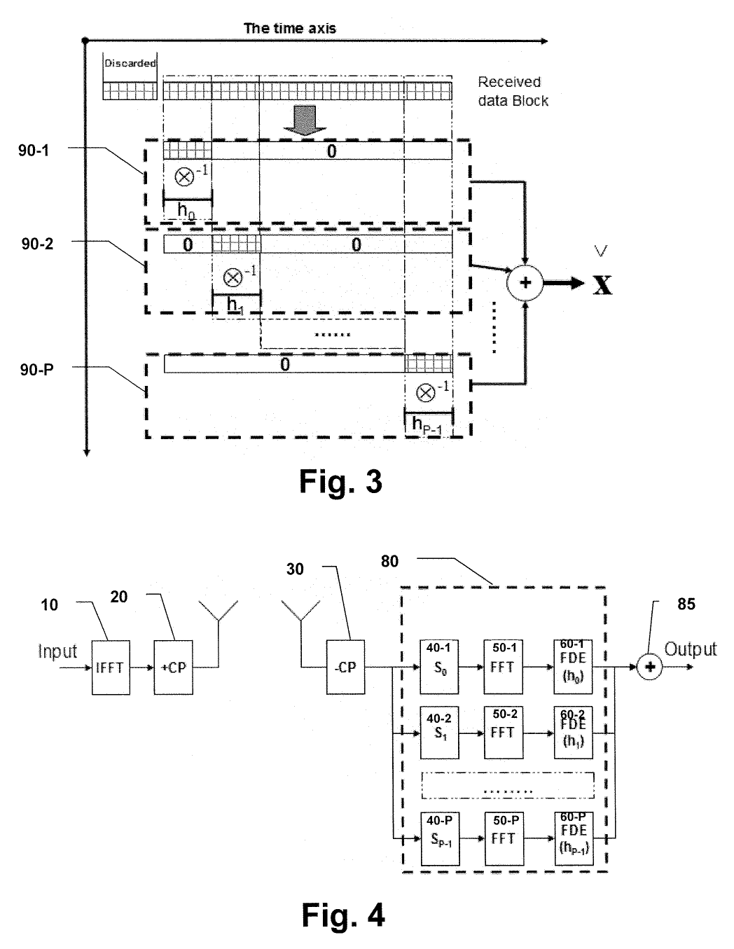

FIG. 3 shows a schematic functional diagram of a subblock-wise equalization process according to one embodiment, which can be regarded as an inverse processing operation comparing with FIG. 2. Again, the horizontal axis is to be interpreted as a time axis, while the vertical axis indicates the equalization process. The proposed subblock-wise frequency domain equalization process suppresses the interference induced by high Doppler.

The M-sized received signal y with removed CP is segmented in respective segmentation stages 90-1 to 90-P into P consecutive B-sized sub-blocks yᵢ, 0≦i≦P−1, where yᵢ=[y]ⱼ, iB≦j≦(i+1)B−1. Such segmentation could be modeled as,

$${y}_{i} = {S}_{i} y , 0 \leq i \leq P - 1 \\ {S}_{i} = {[ \begin{matrix}{0}_{iBxiB} & 0 & 0 \\ 0 & {E}_{BxB} & 0 \\ 0 & 0 & {0}_{( P - i - 1 ) Bx ( P - i - 1 ) B}\end{matrix} ]}_{MxM} \qquad ( 6 )$$

where E_{B×B} is the B-sized identity matrix.

The segmented received signal is then equalized subblock by subblock such as:

$${x}^{⋁} = {\sum }_{i = 0}^{P - 1} {{x}^{⋁}}_{i} \\ {{x}^{⋁}}_{i} = {Λ}_{i}^{- 1} {Qy}_{i} = {Λ}_{i}^{- 1} {QS}_{i} y \qquad ( 7 )$$

where Λᵢ is the M-sized diagonal matrix, such as:

$${Λ}_{i} = diag \{ Q [ \begin{matrix}{h}_{i} \\ {0}_{M - L , 1}\end{matrix} ] \} \qquad ( 8 )$$

As an alternative, instead of transforming the channel impulse response from time domain into frequency domain for each subblock as in equation (8), Λᵢ can also be obtained by channel estimates on preambles and linear interpolation in the frequency domain. Finally, the frequency domain equalized signal can be modeled by summing all the subblock-wise equalized signal, such as:

$${x}^{⋁} = {\sum }_{i = 0}^{P - 1} {{x}^{⋁}}_{i} \qquad ( 9 )$$

FIG. 4 shows a schematic block diagram of the an OFDM transmission system with a receiver or transceiver with subblock-wise FDE according to one embodiment.

In the following, only those units or blocks of FIG. 4 will be described, which differ from FIG. 1. As can be gathered from FIG. 4, a subblock-wise FDE unit 80 is provided, which has P processing branches, each for generating and processing one of subblock in respective segmentation units or blocks 40-1 to 40-P, which can be implemented as register units with selective blanking or resetting options, followed by respective FFT units or blocks 50-1 to 50-P, and respective FDE units 60-1 to 60-P configured to apply equalization in line with a corresponding one of estimated, measured or calculated channel impulse responses h₀ to h_{P-1}.

Finally, the processed and equalized subblocks are combined in a combining unit or block 85.

A complexity comparison between the proposed subblock-wise FDE receiver and conventional full-block FDE receivers for OFDM signals and CP assisted single-carrier signals (CP-SC) is given in Table 1. All signals have the same block size in the comparison.

TABLE 1

| | Conventional | Proposed |
|---|---|---|
| OFDM | 1 × IFFT: M log M multiplications | P × FFT: P × M log M |
| | | multiplication |
| | 1 × FDE: M multiplications | P × FDE: P × M |
| | | multiplications |
| | Totally: M log M + M | Totally: P × (M log M + |
| | | M) |
| CP-SC | 1 × IFFT: M log M multiplications | P × FFT: P × M log M |
| | | multiplication |
| | 1 × FDE: M multiplications | P × FDE: P × M |
| | | multiplications |
| | 1 × FFT: M log M multiplications | 1 × FFT: M log M |
| | | multiplications |
| | Totally: 2 × M log M + M | Totally: (P + 1) × M |
| | | log M + M |

The added complexity by the additional segmentation units 40-1 to 40-P for the subblocks is ignored in Table 1. It can be noticed that the proposed subblock-wise FDE scheme requires P times the complexity of the conventional receiver in OFDM systems, and P/2 times the complexity in CP-SC systems. However, the increased complexity is much smaller than the initially mentioned ISI/ICI cancellation schemes.

In the following, bandwidth efficiency with different FFT sizes is analyzed in Table 2.

TABLE 2

| | Conventional | Conventional | Proposed |
|---|---|---|---|
| | M size | M/2 size | M size |
| OFDM/CP- | M/(M + L) | M/(M + 2L) | M/(M + L) |
| SC | | | |

Assuming an FFT size of 512 bits and a CP length of 16 bits, the corresponding bandwidth efficiencies are 96.97%, 94.49%, and 96.97%, respectively. The proposed scheme achieves 2.52% more bandwidth efficiency than the conventional scheme for half the block size to resist high Doppler.

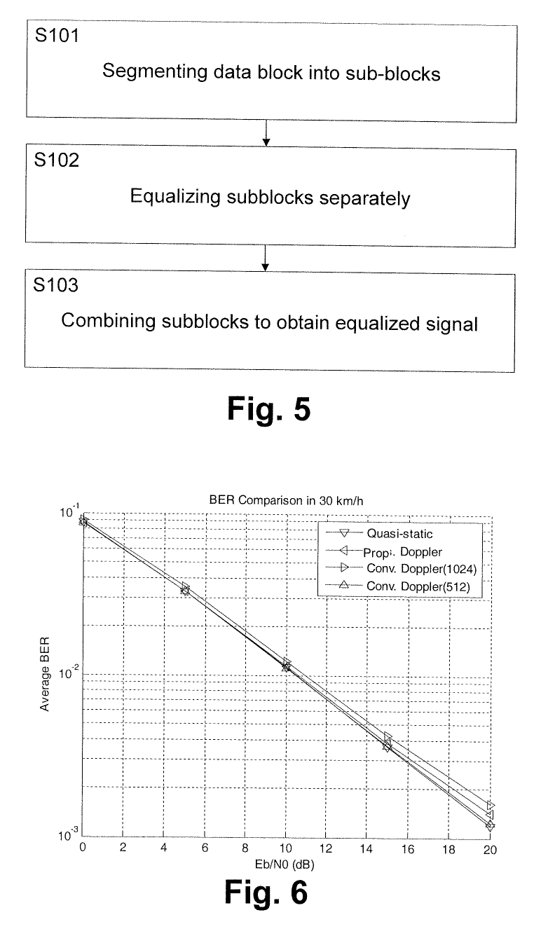

FIG. 5 shows a schematic flow diagram of processing steps of a subblock-wise equalization procedure according to one embodiment.

Initially, in step S101, a received data block is segmented or divided into a predetermined number of subblocks. In this connection is noted that good tradeoff between the complexity increase and performance gain is already achieved at small values of P. It can be noticed from simulation results that the proposed scheme with P=2 (i.e. segmentation into two subblocks) reaches the convergence already. However, with small P values, the increased complexity can be neglected.

In step S102, the subblocks are separately equalized according to allocated channel impulse responses applicable at their timings, e.g., in respective processing branches or by a parallel processing operation. Finally, in step S103, the separately equalized subblocks are combined to obtain a complete equalized output signal.

FIGS. 6 to 8 show diagrams indicating bit error rate (BER) vs. noise ratio Eb/N0 in dB for various alternative systems and obtained by simulation at different velocities of a terminal device comprises the FDE receiver. These various alternative systems are quasi-static OFDM, Conventional FDE with full block size, conventional FDE with half block size, and the proposed FDE according to one embodiment with full block size and subblock number P=2.

The diagram of FIG. 6 was obtained at a receiver velocity of 30 km/h. In case of such a low Doppler interference, the difference between alternative schemes is negligible.

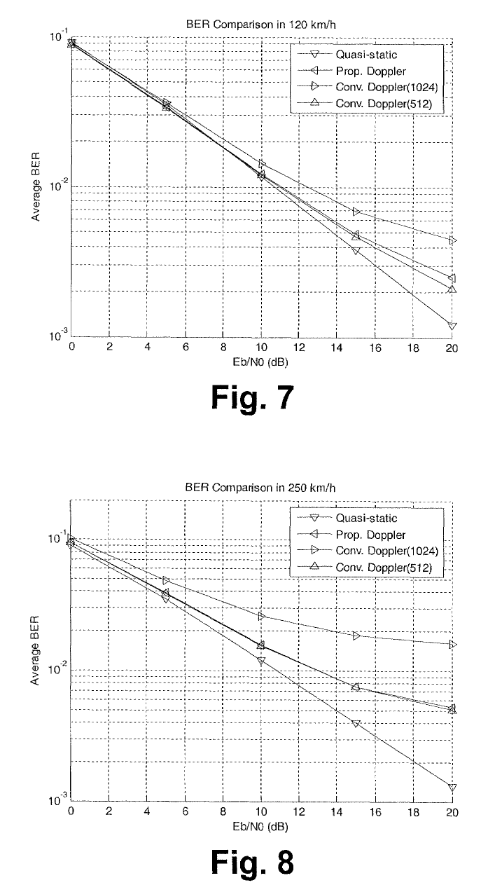

FIG. 7 illustrates the performance behavior at a receiver velocity of 120 km/h. The proposed subblock-wise FDE scheme according to one embodiment outperforms the conventional scheme with full block size by around 2 dB with target BER as 10⁻², and has approximately same performance as the conventional scheme with half block size and ideal FDE in quasi-static channel.

Higher Doppler interference at a receiver velocity of 250 km/h has been evaluated and shown in FIG. 8. The proposed subblock-wise FDE scheme according to one embodiment reaches same performance as the conventional scheme with half-block size, and considerably outperforms the conventional scheme with full block size which cannot reach the target BER level.

The subblock-wise FDE receiver according to one embodiment thus provides resistance to high Doppler interference. Instead of reducing the block size as in conventional solutions to enlarge the subcarrier spacing, it is propose to segment the data block into a number of subblocks, equalize them separately and combined them at final stage. Numerical results proved that the proposed scheme is robust to resist high Doppler interference and can significantly enhance bandwidth efficiency.

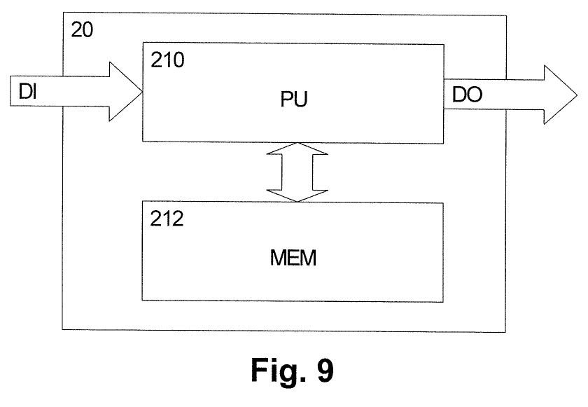

FIG. 9 shows a schematic block diagram of a software-based implementation of the proposed subblock-wise FDE receiver. Here, the receiver shown in FIG. 4 is implemented with a processing unit 210, which may be any processor or computer device with a control unit which performs control based on software routines of a control program stored in a memory 212. Program code instructions are fetched from the memory 212 and are loaded to the control unit of the processing unit 210 in order to perform the processing steps of the above functionalities described in connection with the respective FIGS. 3 and 5 or with the respective blocks of the FDE unit 80 of FIG. 4. These processing steps may be performed on the basis of input data D1 and may generate output data D0, wherein the input data D1 may correspond to the received data blocks and the output data D0 may correspond to the equalized and combined output signal.

To summarize, a method, receiving apparatus and computer program product for subblock-wise frequency domain equalization have been described, wherein a data block of a received signal is segmented into at least two subblocks at a receiving end of a transmission channel. The subblocks are then equalized separately in the frequency domain, and equalized subblocks are combined to obtain an equalized signal. Thereby, Doppler induced interference can be suppressed to achieve enhanced robustness to high Doppler and compensate performance degradation due to rapidly varying channels.

It is to be noted that the invention is not restricted to embodiments described above, but can be implemented in any receiving apparatus involving an equalization scheme in the frequency domain. The embodiment may thus vary within the scope of the attached claims.

1. A method comprising:
segmenting at a receiving end of a transmission channel a data block of a received signal into at least two subblocks;
equalizing said subblocks separately in the frequency domain; and
combining equalized subblocks to obtain an equalized signal.

2. The method according to claim 1, further comprising equalizing said subblocks based on dedicated channel impulse responses of each subblock.

3. The method according to claim 1, further comprising equalizing said subblocks based on channel estimates of preambles and linear interpolation in the frequency domain.

4. The method according to claim 1, comprising serial-to-parallel conversion and fast Fourier conversion for each of said subblocks prior to said equalizing.

5. The method according to claim 1, wherein said received signal is a cyclic prefix assisted single carrier signal.

6. The method according to claim 1, wherein said received signal is an orthogonal frequency division multiplexing signal.

7. A receiving apparatus comprising:
a segmentation unit for segmenting at a receiving end of a transmission channel a data block of a received signal into at least two subblocks;
at least two equalizer units for equalizing said subblocks separately in the frequency domain; and
a combiner unit for combining equalized subblocks to obtain an equalized signal.

8. The receiving apparatus according to claim 7, wherein said at least two equalizer units are configured to equalize said subblocks based on dedicated channel impulse responses of each subblock.

9. The receiving apparatus according to claim 7, wherein said at least two equalizer units are configured to equalize said subblocks based on channel estimates of preambles and linear interpolation in the frequency domain.

10. The receiving apparatus according to claim 7, further comprising at least two respective serial-to-parallel conversion units and at least two respective fast Fourier conversion units for each of said subblocks prior to said at least two equalizer units.

11. The receiving apparatus according to claim 7, wherein said receiving apparatus is configured to receive a cyclic prefix assisted single carrier signal.

12. The receiving apparatus according to claim 7, wherein said receiving apparatus is configured to receive an orthogonal frequency division multiplexing signal.

13. A transceiver apparatus comprising at least one receiving apparatus according to claim 7.

14. A computer program product comprising code means for producing the steps of method claim 1 when run on a computer device.

15. A base station device comprising a receiving apparatus according to claim 7.

16. A mobile terminal comprising a receiving apparatus according to claim 7.

17. A receiver module comprising a receiving apparatus according to claim 7.

18. A transmission system comprising at least one receiving apparatus according to claim 7.
